(19) United States
(12) Patent Application Publication
(10) Pub. No.: US 2022/0049355 A1
(43) Pub. Date: Feb. 17, 2022

(54) SPRAY HEAD, CHEMICAL VAPOR DEPOSITION DEVICE, AND WORKING METHOD OF CHEMICAL VAPOR DEPOSITION DEVICE

(71) Applicant: CHANGXIN MEMORY TECHNOLOGIES, INC., Hefei City (CN)

(72) Inventor: Lifeng Qiu, Hefei (CN)

(21) Appl. No.: 17/409,921

(22) Filed: Aug. 24, 2021

Related U.S. Application Data
(63) Continuation of application No. PCT/CN2021/101428, filed on Jun. 22, 2021.

(30) Foreign Application Priority Data
Aug. 14, 2020 (CN) 202010816497.X

(51) Int. Cl. C23C 16/455

(52) U.S. Cl. CPC C23C 16/45578; C23C 16/458; C23C 16/45587

(57) ABSTRACT

A spray head, a chemical vapor deposition device, and a working method of the chemical vapor deposition device are provided. The spray head includes a shell. A second end of the shell is provided with an air outlet panel, a plurality of air outlet holes are provided on a surface of the air outlet panel, and a middle portion of the surface of the air outlet panel is farther away from a first end than an edge portion.

### CROSS-REFERENCE TO RELATED APPLICATIONS

This is a continuation application of International Patent Application No. PCT/CN2021/101428, filed on Jun. 22, 2021, which claims priority to Chinese Application No. 202010816497.X, filed on Aug. 14, 2020 and entitled “SPRAY HEAD, CHEMICAL VAPOR DEPOSITION DEVICE, AND WORKING METHOD OF CHEMICAL VAPOR DEPOSITION DEVICE”. The disclosures of International Patent Application No. PCT/CN2021/101428 and Chinese Application No. 202010816497.X are incorporated by reference herein in their entireties.

### TECHNICAL FIELD

The disclosure relates to a spray head, a chemical vapor deposition device, and a working method of the chemical vapor deposition device.

### BACKGROUND

In manufacture of integrated circuits (IC), a chemical vapor deposition (CVD) process is mainly adopted to form a thin layer or a film on a semiconductor substrate (such as a wafer). In the chemical vapor deposition process, the semiconductor substrate is exposed to the precursor gas, the precursor gas reacts on a surface of the semiconductor substrate, and a reaction product is deposited on the semiconductor substrate.

### SUMMARY

According to the embodiments, a first aspect of the disclosure provides a spray head. The spray head includes a shell. The shell includes a first end and a second end arranged opposite to each other. The first end of the shell is provided with an air inlet, and the second end of the shell is provided with an air outlet panel. A surface of the air outlet panel is provided with a plurality of air outlet holes. A middle portion of the surface of the air outlet panel is farther away from the first end than an edge portion of the air outlet panel.

According to the embodiments, a second aspect of the disclosure provides a chemical vapor deposition device. The chemical vapor deposition device includes a spray head, and further includes a casing configured to provide a vacuum environment, and a carrier platform configured to mount a semiconductor substrate. The spray head and the carrier platform are arranged in the casing, and the air outlet panel faces the carrier platform. The spray head includes a shell. The shell includes a first end and a second end arranged opposite to each other. The first end of the shell is provided with an air inlet, and the second end of the shell is provided with an air outlet panel. A surface of the air outlet panel is provided with a plurality of air outlet holes. A middle portion of the surface of the air outlet panel is farther away from the first end than an edge portion of the air outlet panel

According to the embodiments, a third aspect of the disclosure provides a working method of a chemical vapor deposition device. The working method includes the following operations. A uniformity of a film deposited on a semiconductor substrate is correspondingly adjusted by adjusting a degree of a middle portion of a surface of an air outlet panel at a second end of a shell of a spray head of the chemical vapor deposition device farther away from the first end of the shell than an edge portion of the air outlet panel. Alternatively, a uniformity of a film deposited on a semiconductor substrate is correspondingly adjusted by adjusting a height difference between a middle portion of a surface of an air outlet panel at a second end of a shell of a spray head of the chemical vapor deposition device and an edge portion of the air outlet panel.

The details of one or more embodiments of the disclosure are set forth in the accompanying drawings and description below. Other features and advantages of the disclosure will be apparent from the specification, the accompanying drawings, and the claims.

### BRIEF DESCRIPTION OF THE DRAWINGS

The accompanying drawings, which constitute a part of the disclosure, are used to provide a further understanding of the disclosure. The illustrative embodiments of the disclosure as well as the illustrations thereof, which are used for explaining the disclosure, do not constitute improper definitions on the disclosure.

In order to describe the technical solutions in the embodiments of the disclosure more clearly, the accompanying drawings required to be used in the embodiments of the disclosure will be simply introduced below. Apparently, the accompanying drawings in the following description show merely some embodiments of the disclosure, and persons of ordinary skill in the art may still derive other drawings from these accompanying drawings without creative effort.

FIG. 1 is a schematic diagram of a spray head provided with an air outlet panel with an inclined angle of a conical surface according to an embodiment of the disclosure.

FIG. 2 is a schematic diagram of a spray head provided with an air outlet panel with another inclined angle of a conical surface according to an embodiment of the disclosure.

FIG. 3 is a schematic diagram of a spray head provided with an air outlet panel with still another inclined angle of a conical surface according to an embodiment of the disclosure.

FIG. 4 is a schematic diagram of a spray head according to another embodiment of the disclosure.

FIG. 5 is a schematic diagram of a spray head according to still another embodiment of the disclosure.

FIG. 6 is a schematic diagram of a spray head according to yet another embodiment of the disclosure.

FIG. 7 is a schematic diagram of a spray head according to yet another embodiment of the disclosure.

FIG. 8 is a schematic diagram of a spray head according to yet another embodiment of the disclosure.

FIG. 9 is a schematic diagram of a spray head in one state according to yet another embodiment of the disclosure.

FIG. 10 is a schematic diagram of a spray head in another state according to yet another embodiment of the disclosure.

FIG. 11 is a simplified schematic diagram of a chemical vapor deposition device according to an embodiment of the disclosure.

FIG. 12 is a simplified schematic diagram of a chemical vapor deposition device according to another embodiment of the disclosure.

### DETAILED DESCRIPTION

In an actual deposition process, a film deposited on a semiconductor substrate with a flat surface generally has poor uniformity. The non-uniformity of the film deposited on the semiconductor substrate may affect the subsequent process, for example, the etching is non-uniform or the chemical grinding of the semiconductor substrate is non-uniform. Finally, the quality of a semiconductor product may be affected.

In order to make the above-mentioned purposes, features and advantages of the disclosure more apparent and understandable, the specific implementations of the disclosure will be described in detail below with reference to the accompanying drawings. Many specific details are set forth in the following description in order to fully understand the disclosure. However, the disclosure can be implemented in many other ways different from those described herein, and those skilled in the art can make similar improvements without departing from the conception of the disclosure. Therefore, the disclosure is not limited by the specific implementations disclosed below.

Generally, a gas outlet surface of a spray head of a traditional chemical vapor deposition device is a plane arranged parallel to a semiconductor substrate. The gas outlet surface of the spray head directly faces the semiconductor substrate, the gas discharged from the gas outlet surface of the spray head reacts on the surface of the semiconductor substrate, and the reaction products are deposited on the semiconductor substrate. However, the film deposited on the surface of the semiconductor substrate is thin in the middle portion of the film and is thick in the edge portion of the film.

In this embodiment, a sub-atmospheric pressure chemical vapor deposition (SACVD) device is taken as an example. In addition, a gas chemical vapor deposition device may also be used. By providing a spray head with a special shape, the uniformity of the deposited film is improved.

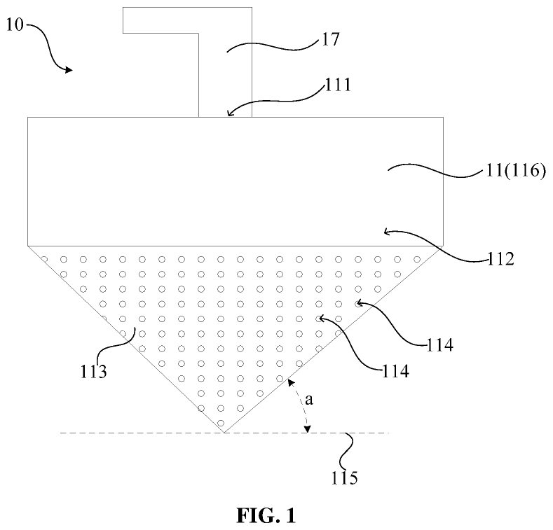

Based on this, referring to FIG. 1, FIG. 1 shows a schematic diagram of a spray head 10 provided with an air outlet panel 113 with an inclined angle of a conical surface according to an embodiment of the disclosure. According to the spray head 10 provided by an embodiment of the disclosure, the spray head 10 includes a shell 11. The shell 11 includes a first end and a second end arranged opposite to each other. The first end is the upper portion of the shell 11 and the second end is the lower portion of the shell 11, as shown in FIG. 1. The first end of the shell 11 is provided with an air inlet 111, and the second end of the shell 11 is provided with an air outlet panel 113. A surface of the air outlet panel 113 is provided with a plurality of air outlet holes 114. A middle portion of a surface of the air outlet panel 113 is farther away from the first end than an edge portion of the air outlet panel.

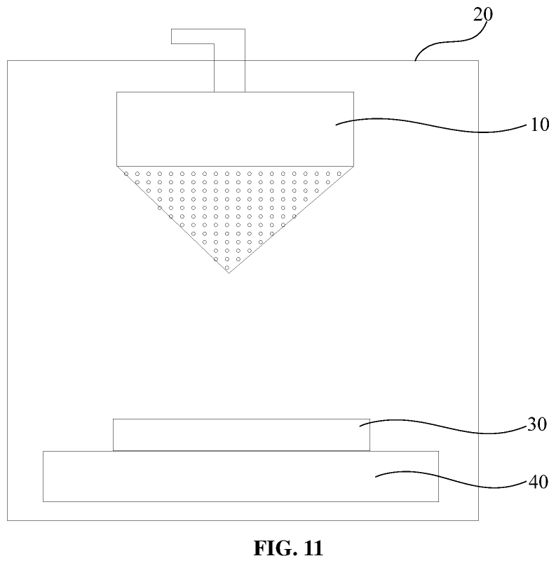

According to the spray head 10 described above, when the chemical vapor deposition process is performed on a semiconductor substrate 30 (shown in FIG. 11), the reaction gas enters the inner cavity of the shell 11 through the air inlet 111, is discharged through the air outlet holes 114 of the air outlet panel 113, and is blown to the semiconductor substrate 30 to be deposited on the surface of the semiconductor substrate 30, so as to form a film. Since the middle portion of the air outlet panel 113 are farther away from the first end than the edge portion, the middle portion of the air outlet panel 113 is closer to the semiconductor substrate 30 than the edge portion of the air outlet panel 113. During the deposition, more particles can be deposited on the middle portion, and the particles deposited from the middle portion to the edge region are gradually reduced. Compared with a traditional flat air outlet panel, the thickness of the middle part of the film deposited on the semiconductor substrate 30 may be relatively increased, so that the uniformity of the film deposited on the surface of the semiconductor substrate 30 is improved.

It should be noted that according to the chemical vapor deposition tests performed under the condition that the degrees of the middle portion of the air outlet panel 113 farther away from the semiconductor substrate 30 than the edge portion are different, when the middle portion of the air outlet panel 113 is closer to the semiconductor substrate 30 than the edge portion, the thickness of the middle part of the film deposited on the surface of the semiconductor substrate 30 may be relatively increased.

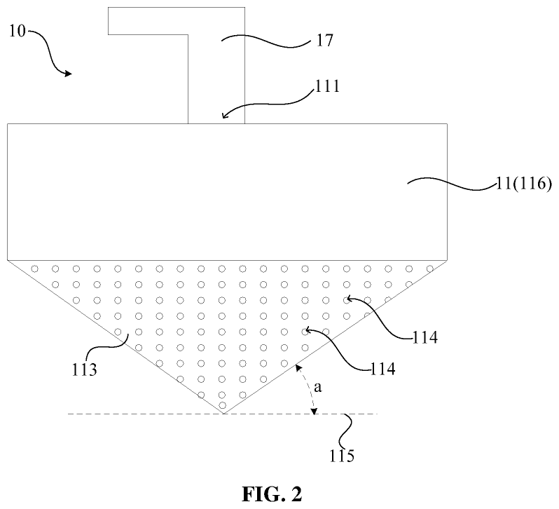

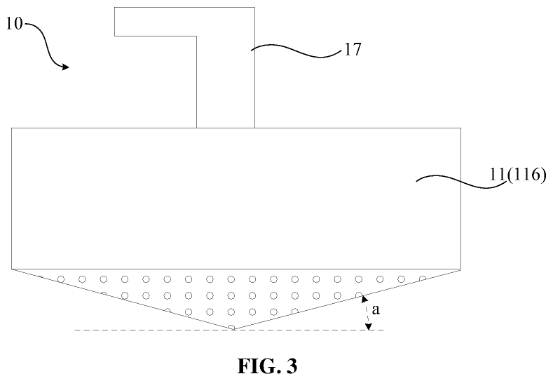

Referring to FIG. 1 to FIG. 3, FIG. 2 shows a schematic diagram of a spray head 10 provided with an air outlet panel 113 with another inclined angle of a conical surface according to an embodiment of the disclosure. FIG. 3 shows a schematic diagram of a spray head 10 provided with an air outlet panel 113 with still another inclined angle of a conical surface according to an embodiment of the disclosure. Further, the air outlet panel 113 is detachably arranged at the second end of the shell 11. The detachable methods include, for example, detachable connection using mounting members such as a screw, a bolt, a snap-fit member, a pin, a rivet, or the like, which is not limited herein. When the air outlet panel 113 is detachably arranged at the second end of the shell 11, the air outlet panels 113 of different shapes may be replaced according to actual situations. Specifically, the degrees of the middle portions of the air outlet panels 113 of different shapes farther away from the first end than the edge portions are different. That is, during the chemical vapor deposition, the degree of closeness of the middle portion of the air outlet panel to the surface of the semiconductor substrate 30 is different. When the thickness of the middle part of the film deposited on the surface of the semiconductor substrate 30 (shown in FIG. 11) needs to be increased, the air outlet panel 113 of which the middle portion is farther away from the first end than the edge portion may be selected (that is, the middle portion of the selected air outlet panel 113 is projected more outwardly). In this way, the middle portion of the air outlet panel 113 is closer to the surface of the semiconductor substrate 30, so that the thickness of the middle part of the film deposited on the surface of the semiconductor substrate 30 may be relatively increased. On the contrary, when the thickness of the middle part of the film deposited on the surface of the semiconductor substrate 30 needs to be reduced, the air outlet panel 113 of which the middle portion closer to the first end than the edge portion may be selected (that is, the middle portion of the selected air outlet panel 113 is projected less outwardly). In this way, the middle portion of the air outlet panel 113 is farther away from the surface of the semiconductor substrate 30, so that the thickness of the middle part of the film deposited on the surface of the semiconductor substrate 30 may be relatively reduced.

Referring to FIG. 1 to FIG. 3, in an embodiment, the air outlet panel 113 is of a structure with a cone shape or a circular truncated cone shape. Therefore, each part of the film deposited on the surface of the semiconductor substrate 30 is relatively uniform. When the spray head 10 directly faces the semiconductor substrate 30 during the chemical vapor deposition process, the surface of the spray head parallel to the semiconductor substrate 30 is selected as a reference surface 115. Specifically, there are multiple air outlet panels 113 of a cone-shaped structure. The angles a between the conical surfaces of the air outlet panels 113 of different shapes and the reference surface 115 are different from each other. If the angle a is larger, it means that the middle portion of the air outlet panel 113 is closer to the semiconductor substrate 30 than the edge portion. If the angle a is smaller, it means that the middle portion of the air outlet panel 113 is farther away from the semiconductor substrate 30 than the edge portion.

Optionally, the air outlet panel 113 may also be of a structure with other irregular shapes, as long as the middle portion of the surface of the air outlet panel 113 is farther away from the first end than the edge portion of the air outlet panel 113. Herein, the structure of the air outlet panel is limited to a structure with a cone shape or a circular truncated cone shape.

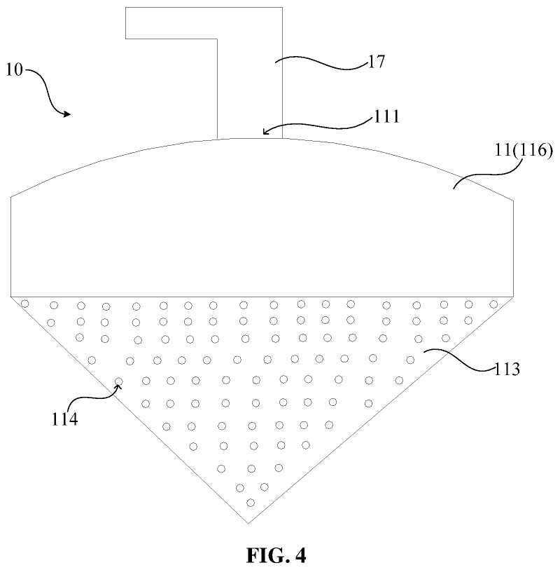

Referring to FIG. 1 and FIG. 4, FIG. 4 shows a schematic diagram of a spray head 10 according to another embodiment of the disclosure. It should be noted that in this embodiment, the semiconductor substrate 30 is specifically a wafer. A main body 116 (the main body 116 refers to the structure of the shell 11 after the air outlet panel 113 is removed) of the shell 11 is, for example, a cylinder, a hemisphere or a structure formed by combining a cylinder and a hemisphere. The projection of the shell 11 on the semiconductor substrate 30 corresponds to the shape of the surface of the semiconductor substrate 30, so that each part of the surface of the semiconductor substrate 30 can be uniformly deposited to form the film. Of course, the main body 116 of the shell 11 is not limited to the above-described structures, but may also be of other irregular structures, which is not repeated herein.

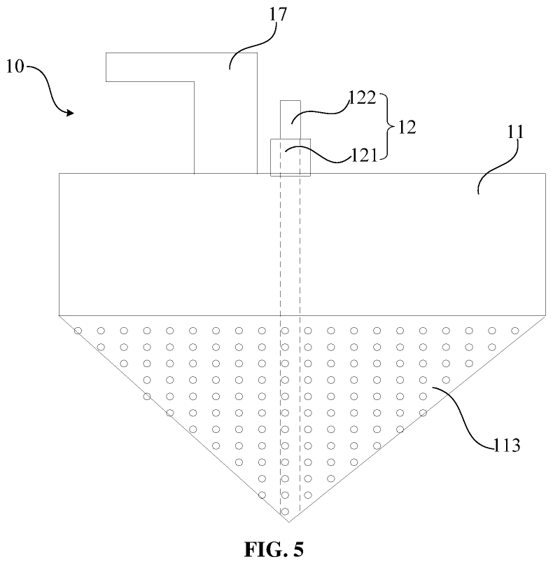

Referring to FIG. 5, FIG. 5 shows a schematic diagram of a spray head 10 according to still another embodiment of the disclosure. In another embodiment, the spray head 10 further includes a driving assembly 12. The air outlet panel 113 is a deformable panel. The driving assembly 12 is arranged on a shell 11, and the driving assembly 12 is configured to drive a middle portion of the deformable panel to telescopically move in a direction away from or close to the first end. Specifically, the deformable panel is, for example, an elastic panel or a flexible material panel, as long as the deformable panel may be correspondingly deformed under the push of the drive assembly 12, which is not limited herein. Taking the deformable panel as an elastic panel as an example, the middle portion of the deformable panel is driven by the driving assembly 12 to move in the direction away from the first end, so that the deformable panel is deformed, and the angle a between the surface of the air outlet panel 113 and the reference surface 115 is increased. In this way, the degree of the middle portion of the surface of the air outlet panel 113 farther away from the first end than the edge portion may be increased. Conversely, when the driving assembly 12 is retracted, the deformable panel recovers under the action of elastic force, and the angle a between the surface of the air outlet panel 113 and the reference surface 115 is reduced.

Further, the driving assembly 12 includes a nut 121 arranged at the first end, and a screw stem 122 cooperating with the nut 121. One end of the screw stem 122 extends out of the shell 11, and another end of the screw stem 122 extends into the shell 11 and is connected to the middle portion of the air outlet panel 113.

As an example, unlike the combined structure in which the nut 121 and the screw stem 122 cooperates with each other, the driving assembly 12 includes a push-pull rod. The push-pull rod penetrates through the shell 11 and extends into the shell 11, and an end of the push-pull rod is connected to the middle portion of the air outlet panel 113. As another example, unlike the combined structure in which the nut 121 and the screw stem 122 cooperates with each other, the driving assembly 12 includes a retractable adjusting rod arranged in the shell 11. An end of the retractable adjusting rod is connected to the middle portion of the air outlet panel 113.

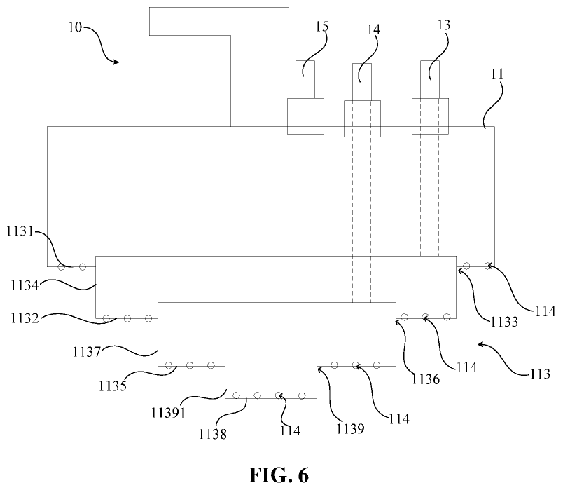

Referring to FIG. 6, FIG. 6 shows a schematic diagram of a spray head 10 according to yet another embodiment of the disclosure. In an embodiment, the spray head 10 further includes a first pushing assembly 13 arranged on a shell 11. The air outlet panel 113 includes a peripheral panel 1131 and a first middle panel 1132 arranged in a middle region of the peripheral panel 1131. The peripheral panel 1131 is fixedly arranged at the second end of the shell 11. A first movable opening 1133 is provided in a middle portion of the peripheral panel 1131. A first windshield sleeve 1134 is arranged around an edge of the first middle panel 1132. The first windshield sleeve 1134 is movably arranged in the first movable opening 1133. The first pushing assembly 13 is connected to the first middle panel 1132 to push the first middle panel 1132 away from or close to the first end. In this way, the position of the first middle panel 1132 may be adjusted by pushing the first middle panel 1132 through the first pushing assembly 13 according to the actual process requirements of chemical vapor deposition. When the first pushing assembly 13 pushes the first middle panel 1132 away from the first end, the middle portion of the air outlet panel 113 may be closer to the semiconductor substrate 30 than the edge portion of the air outlet panel 113. Conversely, when the first pushing assembly 13 pushes the first middle panel 1132 close to the first end, the middle portion of the air outlet panel 113 is farther away from the surface of the semiconductor substrate 30, so that the thickness of the middle part of the film deposited on the surface of the semiconductor substrate 30 is relatively reduced.

It should be noted that the structure of the first pushing assembly 13 is similar to the structure of the driving assembly 12 in the above embodiment. For example, a nut 121 and a screw stem 122 cooperating with the nut 121 are adopted, which is not repeated herein.

It should be noted that in order to improve the uniformity of the film deposited on the semiconductor substrate 30, the air outlet holes 114 are uniformly arranged on the peripheral panel 1131 and the first middle panel 1132. In addition, the air outlet holes 114 may or may not be provided on the wall of the first windshield sleeve 1134, which is not limited herein.

It should be noted that the wall of the first windshield sleeve 1134 functions to allow the gas entering from one end of the first windshield sleeve 1134 to be directed to the other end of the first windshield sleeve 1134, and to be discharged outward from the air outlet holes 114 on the first middle panel 1132.

In an embodiment, in order to ensure a better moving effect of the first windshield sleeve at the first movable opening 1133, the outer wall of the first windshield sleeve is provided with for example a guide rib (not shown in the figures), and the wall of the first movable opening 1133 is provided with for example a recess (not shown in the figures) slidably cooperating with the guide rib. In addition, in another embodiment, the first windshield sleeve is made as a retractable sleeve, one end of the sleeve is connected to the wall of the first movable opening 1133, and the other end of the sleeve is arranged around the edge of the first middle panel 1132 in a circumferential direction. When the first pushing assembly 13 pushes the first middle panel 1132, the sleeve is correspondingly elongated or contracted.

Referring to FIG. 6, furthermore, the spray head 10 further includes a second pushing assembly 14 arranged on the shell 11. The air outlet panel 113 further includes a second middle panel 1135. A second movable opening 1136 is provided in the middle portion of the first middle panel 1132. A second windshield sleeve 1137 is arranged around an edge of the second middle panel 1135. The second windshield sleeve 1137 is movably arranged in the second movable opening 1136. The second pushing assembly 14 is connected to the second middle panel 1135 to push the second middle panel 1135 away from or close to the first end. In this way, the uniformity of the film deposited on the surface of the semiconductor substrate 30 may be improved.

Similar to the first windshield sleeve 1134, the wall of the second windshield sleeve 1137 functions to allow gas entering from one end of the second windshield sleeve 1137 to be directed to the other end of the second windshield sleeve 1137, and to be discharged outward from air outlet holes 114 on the second middle panel 1135.

Referring to FIG. 6, furthermore, the spray head 10 further includes a third pushing assembly 15 arranged on the shell 11. The air outlet panel 113 further includes a third middle panel 1138. A third movable opening 1139 is provided in a middle portion of the second middle panel 1135. A third windshield sleeve 11391 is arranged around an edge of the third middle panel 1138. The third windshield sleeve 11391 is movably arranged in the third movable opening 1139. The third pushing assembly 15 is connected to the third middle panel 1138 to push the third middle panel 1138 away from or close to the first end.

It should be noted that the second pushing assembly 14 and the third pushing assembly 15 are arranged similar to the first pushing assembly 13, which will not be repeated herein. The second windshield sleeve 1137 and the third windshield sleeve 11391 are arranged similar to the first windshield sleeve 1134, which will not be repeated herein.

It should be noted that if the number of the middle panels of the air outlet panel 113 is larger, and the middle panels are sequentially sleeved in one another from the periphery portion to the middle portion of the air outlet panel, it is beneficial to improving the uniformity of the film deposited on the surface of the semiconductor substrate 30. The number of the middle panels of the air outlet panel 113 is not limited to the first middle panel 1132, the second middle panel 1135 and the third middle panel 1138. There may also be a fourth middle panel, a fifth middle panel and the like, which may be set according to actual requirements. In addition, the shape of each panel is not limited to a rectangular shape, and other shapes such as a cone shape or a hemisphere shape are also suitable.

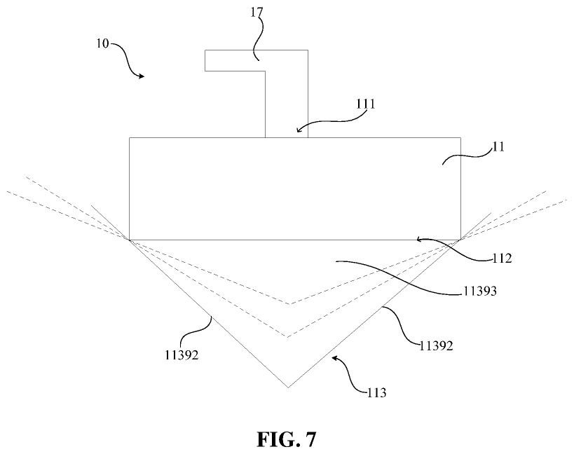

Referring to FIG. 7, FIG. 7 shows a schematic diagram of a spray head 10 according to yet another embodiment of the disclosure. The two dashed lines in FIG. 7 indicate two specific positions to which the air outlet panel 113 may be adjusted. In an embodiment, the air outlet panel 113 includes two rotating panels 11392 and two flexible panels 11393. An air outlet 112 is provided at a second end of the shell 11. One end of one of the two rotating panels 11392 is rotatably connected to one end of the other one of the two rotating panels, and another end of each of the two rotating panels 11392 slidably cooperates with the second end of the shell 11. One of the two flexible panels 11393 is connected to one side of each of the two rotating panels 11392 and to the second end, and the other one of the two flexible panels 11393 is connected to another opposite side of each of the two rotating panels 11392 and to the second end. The two flexible panels 11393 and the two rotating panels 11392 enclose the air outlet 112. The plurality of air outlet holes 114 are provided on the two rotating panels 11392. The air outlet holes 114 may or may not be provided on the two flexible panels 11393, which is not limited herein.

In this way, by adjusting the angle between the two rotating panels 11392, the degree of the connecting portion of the two rotating panels 11392 (corresponding to the middle portion of the air outlet panel 113) farther away from the first end than the edge portion may be adjusted.

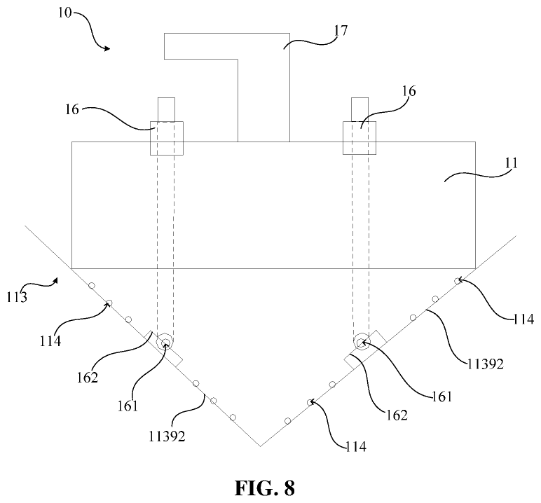

Referring to FIG. 8, FIG. 8 shows a schematic diagram of a spray head 10 according to yet another embodiment of the disclosure. Compared with FIG. 7, a moving assembly 16 is shown in FIG. 8. Furthermore, the spray head 10 further includes a moving assembly 16 arranged on the shell 11. The moving assembly 16 is configured drive the two rotating panels to adjust an angle between two rotating panels 11392. Specifically, there are two moving assemblies 16. Each of the two moving assemblies 16 is arranged corresponding to a respective one of the two rotating panels 11392. An end of each moving assembly 16 is provided with a movable hole 161. Each rotating panel 11392 is provided with a guide beam 162. An end of the guide beam 162 is connected to a respective one of the rotating panels 11392. The guide beam 162 and the respective rotating panel 11392 are spaced apart from each other, and the guide beam 162 penetrates through the movable hole 161. In this way, when the moving assemblies 16 drive the rotating panels 11392 to be adjusted to different angular positions, the end of each of the moving assemblies 16 may be moved relative to the respective rotating panel 11392, but is always connected to the respective rotating panel 11392 through the respective guide beam 162.

It should be noted that the structure of each moving assembly 16 is similar to the structure of the driving assembly 12 in the above embodiment. For example, a nut 121 and a screw stem 122 cooperating with the nut 121 are adopted, which will not be repeated herein.

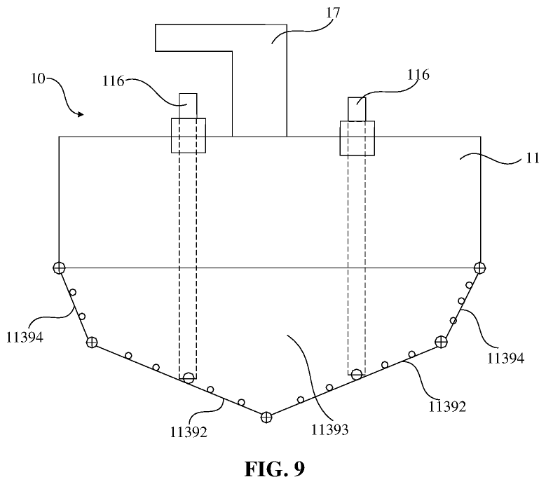

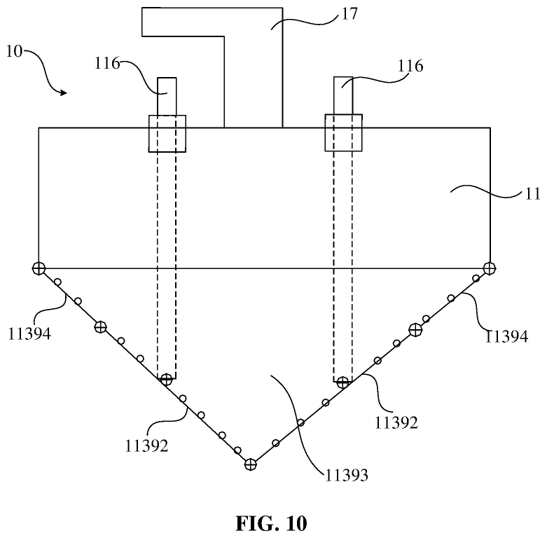

Referring to FIG. 9 and FIG. 10, FIG. 9 shows a schematic diagram of a spray head 10 in one state according to yet another embodiment of the disclosure, and FIG. 10 shows a schematic diagram of a spray head 10 in another state according to yet another embodiment of the disclosure. Compared with FIG. 8, in FIG. 9 and FIG. 10, two rotating connecting panels 11394 are added into the spray head 10 illustrated in FIG. 9 and FIG. 10, so that the connection method of the rotating panels 11392 to the second end is changed. In another embodiment, the spray head 10 further includes a moving assembly 16 arranged on the shell 11. The moving assembly 16 is configured drive the two rotating panels to adjust the angle between the two rotating panels 11392. The air outlet panel 113 includes two rotating panels 11392, two rotating connecting panels 11394 and two flexible panels 11393. An air outlet 112 is provided at the second end of the shell 11. One end of one of the two rotating panels 11392 is rotatably connected to one end of the other one of the two rotating panels, another end of each of the two rotating panels 11392 is rotatably connected to the second end of the shell 11 through a respective one of the two rotating connecting panels 11394. One of the two flexible panels 11393 is connected to one side of each of the two rotating panels 11392, to one side of each of the two rotating connecting panels 11394 and to the second end, and the other one of the two flexible panel 11393 is connected to the another opposite side of each of the two rotating panels 11392, to another opposite side of each of the two rotating connecting panels 11394 and to the second end. The two flexible panels 11393, the two rotating connecting panels 11394 and the two rotating panels 11392 enclose the air outlet 112. The plurality of air outlet holes 114 are provided on the air outlet panel 113 and the two rotating connecting panels 11394. The air outlet holes 114 may or may not be provided on the two flexible panels 11393, which is not limited herein.

In an embodiment, the shell 11 is connected to an air inlet pipe 17. One end of the air inlet pipe 17 communicates with the air inlet 111, another end of the air inlet pipe 17 is configured to be connected to other gas supply devices. The gas supply device delivers the gas into the shell 11 through the air inlet pipe 17.

It should be noted that, in infringement contrast, the “air inlet pipe 17” may be “a part of the shell 11”, that is, the “air inlet pipe 17” is integrally formed with “the other parts of the shell 11”. Alternatively, the “air inlet pipe 17” may also be a separate component which can be separated from “the other parts of the shell 11”, that is, the “air inlet pipe 17” may be manufactured independently, and then be integrally formed with “the other parts of the shell 11”. As shown in FIG. 1, in an embodiment, the “air inlet pipe 17” is a part integrally formed with the “shell 11”.

Referring to FIG. 1 and FIG. 11, FIG. 11 shows a simplified schematic diagram of a chemical vapor deposition device according to an embodiment of the disclosure. In an embodiment, the chemical vapor deposition device includes the spray head 10 described in any of the above embodiments, and further includes a casing 20 configured to provide a vacuum environment, and a carrier platform 40 configured to mount a semiconductor substrate 30. The spray head 10 and the carrier platform 40 are both arranged in the casing 20, and the air outlet panel 113 faces the carrier platform 40.

According to the above-mentioned chemical vapor deposition device, when chemical vapor deposition process is performed on the semiconductor substrate 30, the reaction gas enters the inner cavity of the shell 11 through the air inlet 111, is discharged through the air outlet holes 114 of the air outlet panel 113, and is blown to the semiconductor substrate 30 to be deposited on the surface of the semiconductor substrate 30, so as to form a film. Since the middle portion of the air outlet panel 113 is farther away from the first end than the edge portion, the middle portion of the air outlet panel 113 is closer to the semiconductor substrate 30 than the edge portion of the air outlet panel 113. Compared with a traditional flat air outlet panel 113, the thickness of the middle part of the film deposited on the semiconductor substrate 30 may be relatively increased, so that the uniformity of the film deposited on the surface of the semiconductor substrate 30 may be improved.

The chemical vapor deposition device may be a plasma-enhanced chemical vapor deposition (PECVD) device, an atmospheric pressure chemical vapor deposition (atmospheric pressure CVD) device, or a metal organic chemical vapor deposition (metal organic CVD) device.

It should be noted that, specifically, the carrier platform 40 is, for example, a suction cup. A diameter of the suction cup is substantially the same as a diameter of the spray head 10. The suction cup is movable vertically along an axis. The movable carrier platform 40 is configured to adjust its position in a vacuum chamber. A heating system or a cooling system may be provided in the carrier platform 40, so as to heat or cool the semiconductor substrate 30 and/or to heat or cool the wall of the vacuum chamber. The plasma-enhanced chemical vapor deposition process is a process that may deposit films of various materials on the semiconductor substrate 30 at a temperature lower than the temperature of the standard chemical vapor deposition (CVD) process. A direct current (DC) power supply or a radio frequency (RF) power supply may be coupled to the vacuum chamber to generate plasma during the plasma-enhanced chemical vapor deposition process. In the plasma-enhanced chemical vapor deposition process, deposition is realized by introducing the reactive gas between parallel electrodes (RF-energized electrodes or DC electrodes and grounded electrodes). Alternatively, the chamber may have a coil to generate inductively coupled plasma with a high density. In any case, the spray head 10 in the above embodiment plays an important role in the uniformity of the obtained film. Capacitive coupling between electrodes excites the reactive gas into plasma, which initiates a chemical reaction and causes the reaction product to be deposited on the semiconductor substrate 30. The semiconductor substrate 30 placed on the grounded electrode may be heated to 250° C. to 350° C., depending on the specific film requirements.

In contrast, standard chemical vapor deposition without plasma excitation may require higher temperatures, such as being heated to a range from 600° C. to 800° C. Since the temperature of chemical vapor deposition may damage the device being manufactured, a lower deposition temperature is critical in many applications. Films generally deposited through the plasma-enhanced chemical vapor deposition process are made of silicon nitride (SiₓN_{y}), silicon dioxide (SiO₂), silicon oxynitride (SiOₓN_{y}), silicon carbide (SiC), and amorphous silicon (α-Si). Silane (SiH₄) (silicon source gas) is mixed with oxygen source gas to form silicon dioxide, or silane (silicon source gas) is mixed with nitrogen source gas to form silicon nitride. In some embodiments, an oxide layer is formed by using a tetraethylorthosilicate (TEOS) material through the plasma-enhanced chemical vapor deposition process (that is, a plasma enhanced TEOS (PETEOS) process). By plasma excitation, a high deposition rate may be obtained through tetraethoxysilane/oxygen.

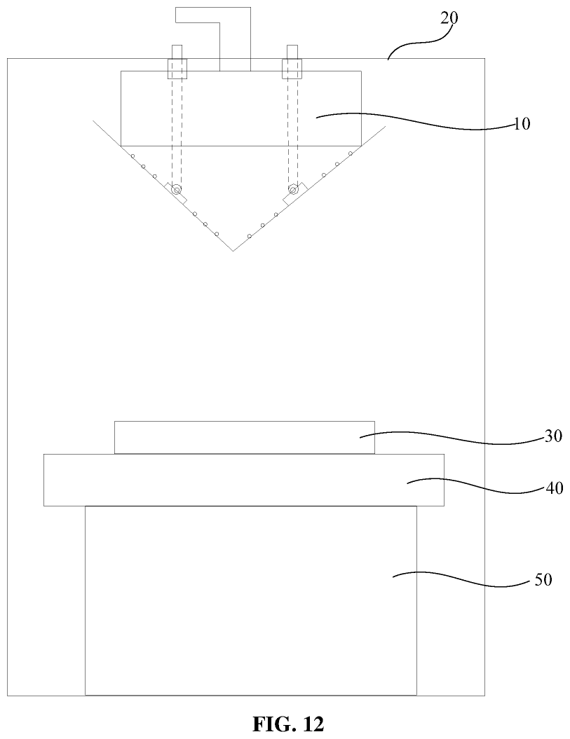

Referring to FIG. 8 and FIG. 12, FIG. 12 shows a simplified schematic diagram of a chemical vapor deposition device according to an embodiment of the disclosure. In an embodiment, the chemical vapor deposition device further includes a rotating mechanism 50. The rotating mechanism 50 is configured to drive the carrier platform 40 into rotation. In this way, the rotating mechanism 50 drives the carrier platform 40 into rotation, and therefore correspondingly drives the semiconductor substrate 30 on the carrier platform 40 into rotation, so that the uniformity of the film deposited on the semiconductor substrate 30 may be improved.

In an embodiment, a working method of the chemical vapor deposition device according to any of the above embodiments includes the following operations. A uniformity of a film deposited on a semiconductor substrate 30 is correspondingly adjusted by adjusting a degree of a middle portion of a surface of an air outlet panel 113 farther away from the first end than the edge portion of the air outlet panel. Alternatively, a uniformity of a film deposited on a semiconductor substrate 30 is correspondingly adjusted by adjusting a height difference between a middle portion of a surface of an air outlet panel 113 and an edge portion of the air outlet panel 113.

With the working method of the chemical vapor deposition device, compared with a traditional flat air outlet panel 113, the thickness of the middle part of the film deposited on the semiconductor substrate 30 may be relatively increased, so that the uniformity of the film deposited on the surface of the semiconductor substrate 30 may be improved.

The technical features of the embodiments described above can be arbitrarily combined. In order to make the description simple, not all the possible combinations of the technical features in the above embodiments are completely described. However, all of the combinations of these technical features should be considered as within the scope described in the present specification as long as there is no contradiction in the combinations of these technical features.

The above embodiments merely illustrate several implementations of the disclosure, and the description thereof is specific and detailed, but they are not constructed as limiting the patent scope of disclosure. It should be noted that a number of variations and improvements made by those of ordinary skill in the art without departing from the conception of the disclosure are within the protection scope of the disclosure. Therefore, the patent protection scope of the present disclosure should be subject to the appended claims.

In the description of the disclosure, it should be noted that terminologies of “central”, “longitudinal”, “transversal”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, and the like that indicate relations of directions or positions are based on the relations of directions or positions shown in the drawings, which are only to facilitate description of the disclosure and to simplify the description of the disclosure, rather than to indicate or imply that the referred device or element is limited to the specific direction or to be operated or configured in the specific direction. Therefore, the above-mentioned terminologies shall not be interpreted as confine to the present disclosure.

In addition, terms “first” and “second” are only adopted for description and should not be understood to indicate or imply relative importance or implicitly indicate the number of indicated technical features. Therefore, a feature defined by “first” and “second” explicitly or implicitly indicates inclusion of at least one such feature. In the description of the disclosure, “multiple” means two or more, for example, two, three and the like, unless otherwise limited definitely and specifically.

In the disclosure, unless otherwise definitely specified and limited, terms “install”, “mutually connect”, “connect”, “fix” and the like should be broadly understood. For example, the terms may refer to fixed connection and may also refer to detachable connection or integration. The terms may refer to mechanical connection and may also refer to electrical connection. The terms may refer to direct mutual connection, may also refer to indirect connection through a medium and may refer to communication in two components or an interaction relationship of the two components. For those of ordinary skill in the art, specific meanings of these terms in the disclosure can be understood according to a specific condition.

In the disclosure, unless otherwise definitely specified and limited, a first feature being “above” or “below” a second feature may include the first feature and the second feature being in direct contact, or the first feature and the second feature being in contact through an intermediary. Moreover, the first feature being “over”, “above”, and “on” the second feature may be that the first feature is right above or not right above the second feature, or merely means that the level of the first feature is higher than that of the second feature. The first feature being “under”, “below”, and “beneath” the second feature may be that the first feature is directly below or not directly below the second feature, or merely means that the level of the first feature being lower than that of the second feature.

It should be noted that when an element is referred to as being “fixed to” or “disposed on” another element, it can be directly on the other element or an intervening element may also be present. When an element is referred to as being “connected” to another element, it can be directly connected to the other element or an intervening element may be present concurrently. The terms “vertical”, “horizontal”, “upper”, “lower”, “left”, “right”, and similar expressions used herein are for illustrative purposes only and do not mean the only implementations.

1. A spray head, comprising:
a shell, wherein the shell comprises a first end and a second end arranged opposite to each other, the first end of the shell is provided with an air inlet, the second end of the shell is provided with an air outlet panel, a surface of the air outlet panel is provided with a plurality of air outlet holes, and a middle portion of the surface of the air outlet panel is farther away from the first end than an edge portion of the air outlet panel.

2. The spray head of claim 1, wherein the air outlet panel is detachably arranged at the second end of the shell.

3. The spray head of claim 2, wherein the air outlet panel is of a structure with a cone shape or a circular truncated cone shape.

4. The spray head of claim 1, wherein the spray head further comprises a driving assembly, the air outlet panel is a deformable panel, the driving assembly is arranged on the shell, and the driving assembly is configured to drive a middle portion of the deformable panel to move in a direction away from the first end.

5. The spray head of claim 4, wherein the driving assembly comprises a nut arranged at the first end and a screw stem cooperating with the nut, one end of the screw stem extends out of the shell, and another end of the screw stem extends into the shell and is connected to the middle portion of the air outlet panel.

6. The spray head of claim 4, wherein the driving assembly comprises a push-pull rod, the push-pull rod penetrates through the shell and extends into the shell, and an end of the push-pull rod is connected to the middle portion of the air outlet panel.

7. The spray head of claim 4, wherein the driving assembly comprises a retractable adjusting rod arranged in the shell, and an end of the retractable adjusting rod is connected to the middle portion of the air outlet panel.

8. The spray head of claim 1, wherein the spray head further comprises a first pushing assembly arranged on the shell, the air outlet panel comprises a peripheral panel and a first middle panel arranged in a middle region of the peripheral panel, the peripheral panel is fixedly arranged at the second end of the shell, a first movable opening is provided in a middle portion of the peripheral panel, a first windshield sleeve is arranged around an edge of the first middle panel, the first windshield sleeve is movably arranged in the first movable opening, the first pushing assembly is connected to the first middle panel to push the first middle panel away from or close to the first end.

9. The spray head of claim 8, wherein the spray head further comprises a second pushing assembly arranged on the shell, the air outlet panel further comprises a second middle panel, a second movable opening is provided in a middle portion of the first middle panel, a second windshield sleeve is arranged around an edge of the second middle panel, the second windshield sleeve is movably arranged in the second movable opening, and the second pushing assembly is connected to the second middle panel to push the second middle panel away from or close to the first end.

10. The spray head of claim 1, wherein the air outlet panel comprises two rotating panels and two flexible panels, an air outlet is provided at the second end of the shell, one end of one of the two rotating panels is rotatably connected to one end of the other one of the two rotating panels, another end of each of the two rotating panels slidably cooperates with the second end of the shell, one of the two flexible panels is connected to one side of each of the two rotating panels and to the second end, the other one of the two flexible panels is connected to another opposite side of each of the two rotating panels and to the second end, the two flexible panels and the two rotating panels enclose the air outlet, and the plurality of air outlet holes are provided on the two rotating panels.

11. The spray head of claim 10, wherein the spray head further comprises a moving assembly arranged on the shell, and the moving assembly is configured to drive the two rotating panels to adjust an angle between the two rotating panels.

12. The spray head of claim 1, wherein the spray head further comprises a moving assembly arranged on the shell, the air outlet panel comprises two rotating panels, two rotating connecting panels and two flexible panels, the moving assembly is configured to drive the two rotating panels to adjust an angle between the two rotating panels, an air outlet is provided at the second end of the shell, one end of one of the two rotating panels is rotatably connected to one end of the other one of the two rotating panels, another end of each of the two rotating panels is rotatably connected to the second end of the shell through a respective one of the two rotating connecting panels, one of the two flexible panels is connected to one side of each of the two rotating panels, to one side of each of the two rotating connecting panels and to the second end, the other one of the two flexible panels is connected to another opposite side of each of the two rotating panels, to another opposite side of each of the two rotating connecting panels and to the second end, the two flexible panels, the two rotating connecting panels and the two rotating panels enclose the air outlet, and the plurality of air outlet holes are provided on the two rotating panels and the two rotating connecting panels.

13. The spray head of claim 9, wherein the spray head further comprises a third pushing assembly arranged on the shell, the air outlet panel further comprises a third middle panel, a third movable opening is provided in a middle portion of the second middle panel, a third windshield sleeve is arranged around an edge of the third middle panel, the third windshield sleeve is movably arranged in the third movable opening, and the third pushing assembly is connected to the third middle panel to push the third middle panel away from or close to the first end.

14. The spray head of claim 1, wherein the shell is connected to an air inlet pipe, one end of the air inlet pipe communicates with the air inlet, another end of the air inlet pipe is configured to be connected to a gas supply device, and the gas supply device delivers gas into the shell through the air inlet pipe.

15. The spray head of claim 1, wherein a main body of the shell is a cylinder, a hemisphere or a structure formed by combining a cylinder and a hemisphere.

16. The spray head of claim 4, wherein the deformable panel is an elastic panel or a flexible material panel.

17. A chemical vapor deposition device, comprising a spray head, and further comprising a casing configured to provide a vacuum environment, and a carrier platform configured to mount a semiconductor substrate, the spray head and the carrier platform being arranged in the casing, and an air outlet panel facing the carrier platform, wherein the spray head comprises a shell, the shell comprising a first end and a second end arranged opposite to each other, the first end of the shell being provided with an air inlet, the second end of the shell being provided with the air outlet panel, a surface of the air outlet panel being provided with a plurality of air outlet holes, and a middle portion of the surface of the air outlet panel being farther away from the first end than an edge portion of the air outlet panel.

18. The chemical vapor deposition device of claim 17, wherein the chemical vapor deposition device further comprises a rotating mechanism configured to drive the carrier platform into rotation.

19. The chemical vapor deposition device of claim 17, wherein the carrier platform is a suction cup, a diameter of the suction cup is substantially the same as a diameter of the spray head, and the suction cup is movable vertically along an axis.

20. A working method of a chemical vapor deposition device, comprising:
adjusting a uniformity of a film deposited on a semiconductor substrate correspondingly by adjusting a degree of a middle portion of a surface of an air outlet panel at a second end of a shell of a spray head of the chemical vapor deposition device farther away from a first end of the shell than an edge portion of the air outlet panel; or
adjusting a uniformity of a film deposited on a semiconductor substrate correspondingly by adjusting a height difference between a middle portion of a surface of an air outlet panel at a second end of a shell of a spray head of the chemical vapor deposition device and an edge portion of the air outlet panel.
